(19) United States
(12) Patent Application Publication
(10) Pub. No.: US 2012/0000606 A1
(43) Pub. Date: Jan. 5, 2012

(54) PLASMA UNIFORMITY SYSTEM AND METHOD

(75) Inventors: Rajesh Dorai, Woburn, MA (US); Kamal Hadidi, Somerville, MA (US); Mayur Jagtap, Burlington, MA (US)

(73) Assignee: Varian Semiconductor Equipment Associates, Inc., Gloucester, MA (US)

(21) Appl. No.: 12/829,497

(22) Filed: Jul. 2, 2010

(51) Int. Cl. C23F 1/08; C23C 16/50; H05B 31/02; C23C 16/458

(52) U.S. Cl. 156/345.1; 156/345.51; 118/723 R; 315/111.21

(57) ABSTRACT

A plasma processing tool comprises a plasma chamber configured to generate a plasma from a gas introduced into the chamber where the generated plasma has an electron plasma frequency. A plurality of electrodes disposed within the chamber. Each of the electrodes configured to create a rapidly-rising-electric-field pulse in a portion of the plasma contained in the chamber. Each of said rapidly-rising-electric-field pulses having a rise time substantially equal to or less than the inverse of the electron plasma frequency and a duration of less than the inverse of the ion plasma frequency. In this manner, the electron energy distribution in the generated plasma may be spatially and locally modified thereby affecting the density, composition and temperature of the species in the plasma and consequently the uniformity of the density and composition of ions and neutrals directed at a target substrate.

### BACKGROUND OF THE INVENTION

1. Field of the Invention

Embodiments of the invention relate to the field of plasma processing systems. More particularly, the present invention relates to an apparatus and method for controlling the uniformity of a plasma process applied to a substrate.

2. Discussion of Related Art

Plasmas are used in a variety of ways in semiconductor processing to implant wafers or substrates with various dopants, to deposit or to etch thin films. Such processes involve the directional deposition or doping of ions on or beneath the surface of a target substrate. Other processes include plasma etching, where the directionality of the etching species determines the quality of the trenches to be etched.

Generally, plasmas are generated by supplying energy to a neutral gas introduced into a chamber to form charged carriers which are implanted into the target substrate. For example, plasma doping (PLAD) systems are typically used when shallow junctions are required in the manufacture of semiconductor devices where lower ion implant energies confine the dopant ions near the surface of the wafer. In these situations, the depth of implantation is related to the voltage applied to the substrate. In particular, a wafer is positioned on a platen, which functions as a cathode, within the chamber. An ionizable gas containing the desired dopant materials is introduced into the plasma chamber. The gas is ionized by any of several methods of plasma generation, including, but not limited to DC glow discharge, capacitively coupled RF, inductively coupled RF, etc.

Once the plasma is generated, there exists a plasma sheath between the plasma and all surrounding surfaces, including the workpiece. The sheath is essentially a layer in the plasma which has a greater density of positive ions (i.e. excess positive charge) than the density of negatively charged species. The platen and substrate are then biased with a negative voltage in order to cause the ions from the plasma to cross the plasma sheath and be implanted into or deposited on the wafer at a depth proportional to the applied bias voltage.

In co-pending application Ser. No. 12/496,080 assigned to the assignee of the present application and incorporated herein by reference, rapidly rising electric-field (“E-field”) pulses are used to modify the energy distribution of the electrons in a plasma. In particular, when an E-field pulse is applied to a plasma, the ion density and composition can be modified. The pulses are long enough to influence the electrons, but too short to significantly affect the ions due to the relatively greater mass of the ions which don't have enough time to respond to these pulses.

By carefully controlling the electron energy, the plasma composition can be optimized to meet the requirements of the specific process which may entail modifying the ratio of ion species in the plasma, changing the ratio of ionization to dissociation, or changing the excited state population of the plasma. In addition, by selectively controlling the local electron energy distribution, the plasma ion/neutral composition and uniformity can likewise be controlled locally. Thus, there is a need to locally modify the electron energy distribution of a plasma to spatially control the density, composition and temperature of the charged and non-charges species in a plasma.

### SUMMARY OF THE INVENTION

Exemplary embodiments of the present invention are directed to an apparatus and method for controlling the uniformity of a process in plasma chamber. In an exemplary embodiment, a plasma processing tool comprises a plasma chamber configured to generate a plasma from a gas introduced into the chamber where the generated plasma has an electron plasma frequency. One or more electrodes are disposed within the chamber. Each of the electrodes is configured to create a rapidly-rising-electric-field pulse in the plasma contained in the chamber. The rapidly-rising-electric-field pulses have a rise time substantially equal to or less than the inverse of the electron plasma frequency and each pulse has a duration of less than the inverse of the ion plasma frequency. In this manner, the electron energy distribution in the generated plasma may be spatially and locally modified thereby affecting the density, composition and temperature of the species in the plasma and consequently the uniformity of the ions directed at a target substrate.

A method for modifying an electron energy distribution of a plasma is disclosed comprising providing a feed gas to a chamber and exciting the feed gas to generate a plasma having ions, electrons and neutrals. A rapidly-rising-electric-field pulse is selectively applied through selected ones of a plurality of electrodes disposed within the chamber. An electric field is generated in the plasma from the selected ones of the plurality of electrodes. The uniformity of particular groupings of ions, electrons and neutrals in the plasma are affected based on the generation of the corresponding electric fields by the selected electrodes.

### BRIEF DESCRIPTION OF THE DRAWINGS

FIG. 1 is a schematic illustration of a plasma chamber in accordance with an exemplary embodiment of the present disclosure.

FIG. 2 is a perspective view of an exemplary electrode assembly in accordance with an embodiment of the present disclosure.

FIG. 2A is a perspective view of a plasma chamber utilizing the electrode assembly in accordance with an embodiment of the present disclosure.

FIGS. 2B-2D illustrate exemplary E-field contours resulting from various voltages applied to the electrodes in accordance with an embodiment of the present disclosure.

FIGS. 2E-2G illustrate exemplary E-field vectors corresponding to conditions of FIGS. 2B-2D applied to the electrodes in accordance with an embodiment of the present disclosure.

FIG. 3A is a perspective view of an alternative embodiment of a plasma chamber utilizing an electrode assembly in accordance with an embodiment of the present disclosure.

FIGS. 3B-3D illustrate exemplary E-field contours resulting from various voltages applied to the electrodes in accordance with an embodiment of the present disclosure.

FIGS. 3E-3G illustrate exemplary E-field vectors corresponding to conditions of FIGS. 3B-3D applied to the electrodes in accordance with an embodiment of the present disclosure.

FIG. 4A is a general side view of a plasma chamber utilizing a particularly shaped baffle to provide various E-fields in a generated plasma in accordance with an embodiment of the present disclosure.

FIG. 4B illustrate exemplary E-field contours resulting from various voltages applied to the baffle of FIG. 4A in accordance with an embodiment of the present disclosure.

FIG. 4C illustrate exemplary E-field vectors corresponding to conditions of FIG. 4B applied to the baffle in accordance with an embodiment of the present disclosure.

FIG. 5 is a flow chart illustrating the steps of plasma uniformity in accordance with an embodiment of the present disclosure.

### DESCRIPTION OF EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, like numbers refer to like elements throughout.

An apparatus and method are disclosed for selectively and/or locally controlling the electron energy distribution (EED) in a plasma which effects the electron impact processes therein such as ionization and dissociation. By locally controlling the EED within the plasma, the ion and neutral compositions and densities may be modified thereby controlling uniformity of implantation into a target substrate. The disclosed method and apparatus may be implemented in PLAD systems, but may also be utilized with any plasma processing tool.

With plasmas, it is desirable to have the ability to selectively modify the ion and radical composition to increase the concentration of desired particle types and decrease the concentration of undesired particle types. By using a rapidly-rising-electric-field pulse or pulses generated from a plurality of ring electrodes and directed at particular portions of the plasma, energy of electrons in the plasma can be selectively modified, which in turn, can result in a modification of the charged and non-charged species' composition and density in the plasma. In this manner, the uniformity of the ion and neutrals of the plasma may be controlled, thereby providing desired implant or deposition characteristics in and on a target substrate.

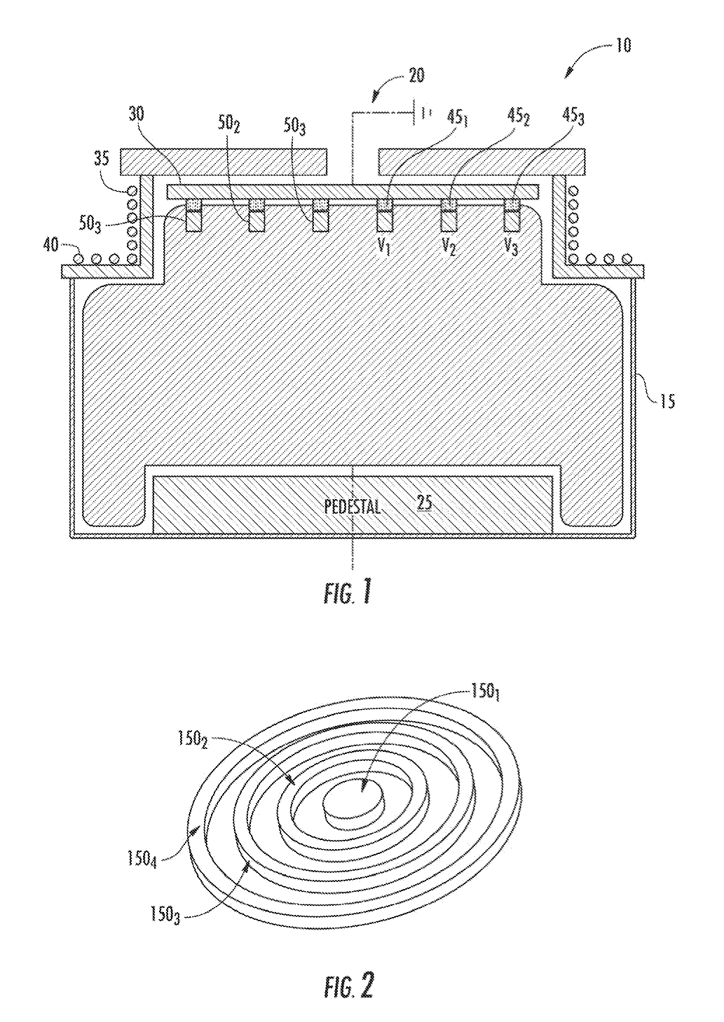

FIG. 1 is a schematic illustration of a simplified PLAD tool 10 utilizing an electrode assembly configured to generate rapidly-rising-electric-field pulses directed at a plasma in a plasma chamber 15. A pedestal or platen 25 is positioned within chamber 15 and provides a surface for supporting a workpiece or substrate, such as a semiconductor wafer, as well as providing an electrical connection thereto. Plasma chamber 15 includes an aperture 20 through which an ionizable gas containing a desired dopant for implantation into the substrate is supplied. The source gas may be, for example, BF₃, B₂H₆, PF₃, etc. A baffle 30 is used to disperse the supplied ionizable source gas into chamber 15 toward the substrate. RF power is supplied to a plurality of vertical coils 35 and horizontal coils 40 disposed around the walls of chamber 15 which form an anode. This RF energy ionizes the source gas supplied to chamber 15 to create plasma 5 having the desired dopant characteristics. A negative voltage is applied to pedestal 25 and to the target substrate which acts as a cathode to attract the plasma ions across the plasma sheath. The ions within the plasma accelerate and implant into or deposit on the target substrate as an ion dose to form areas of impurity dopants. Generally, the ion dose is the amount of ions implanted into the target substrate or the integral over time of the ion current. The applied voltage corresponds to the implantation depth of the ions which may also be influenced by the pressure and flow rate of the gas introduced into chamber 15, duration of the bias voltage, etc.

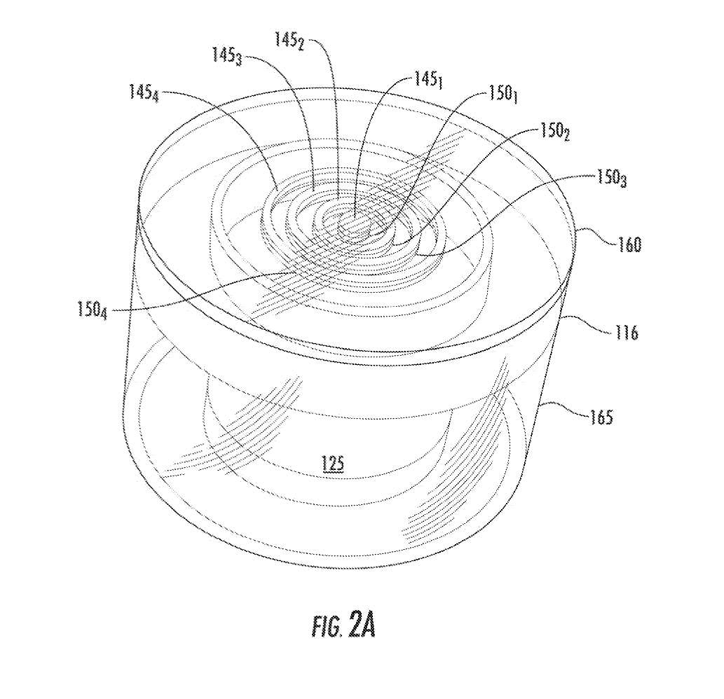

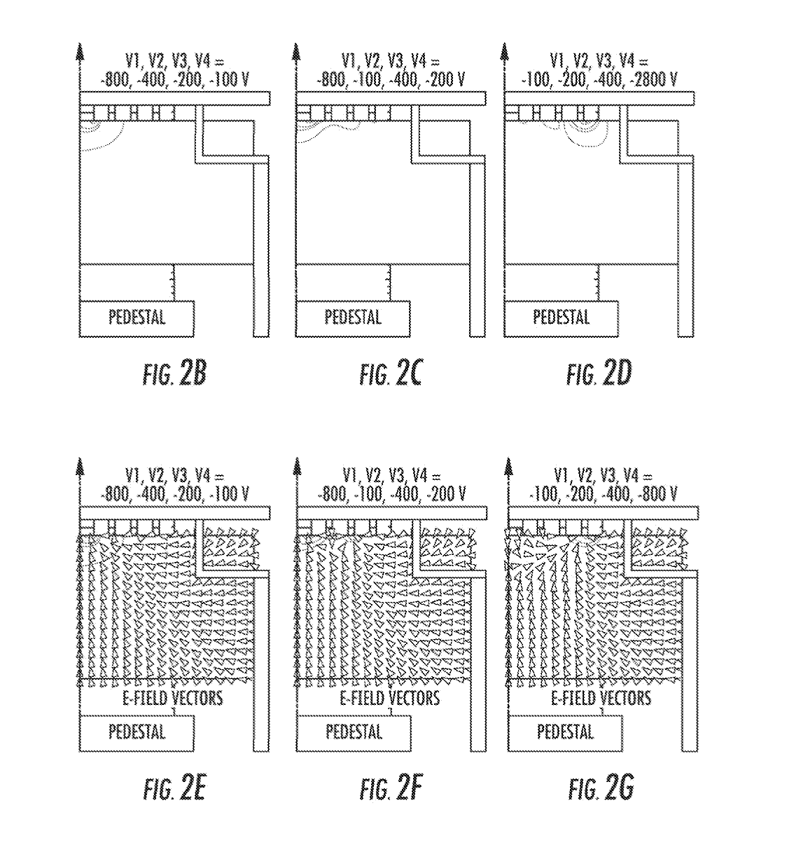

The electrode assembly is defined by a plurality of electrodes 50₁ . . . 50₃ disposed between the baffle 30 and the pedestal 25 and may or may not be in contact with the plasma. Although three electrodes (50₁ . . . 50₃) are shown in FIG. 1, additional or fewer electrodes may be employed depending on the generation of electric fields and associated granularity of uniformity control. Alternatively, a single electrode may also be employed between the baffle 30 and pedestal 25 to generate a desired electric field. In addition, insulators 45₁ . . . 45_{N} are disposed between the corresponding electrodes 50₁ . . . 50₃ and baffle 30 to insulate each of the electrodes from the baffle which is connected to ground. Each of the plurality of electrodes 50₁ . . . 50₃ is configured to create a rapidly-rising-electric-field pulse in the plasma from a pulse generator (not shown) to selectively generate an electric field in the plasma 5. The rapidly-rising-electric-field pulses have a rise time substantially equal to or less than the inverse of the electron plasma frequency and each pulse has a duration of less than the inverse of the ion plasma frequency. For example, electrode 50₁ may be biased with a voltage V₁ to generate one electric field pattern within the plasma 5. Electrode 50₂ may be biased with a voltage V₂ to generate a different electric field pattern in plasma 5. Electrode 50₃ may be biased with a voltage V₃ to generate a different electric field pattern in plasma 5 as compared to electrode 50₂. A few sample voltages and electric fields generated are illustrated in FIGS. 2-4 associated with different electrode/baffle configurations.

Each of the rapidly-rising-electric-fields supplied by the electrodes 50₁ . . . 50₃ creates a voltage gradient locally across the plasma 5 proximate the respective electrode on a time scale that is much shorter than the plasma response time. The rapidly-rising-electric-field pulses produce an electric field in the plasma which drives an increase in electron energy. Since the pulses are so short, only the electrons in the plasma 5 proximate the respective electrode 50₁ . . . 50₃ are influenced by the electric field, while the relatively heavy ions are not. This makes it possible to control electron energy separately from the ions of the plasma. However, this response time is typically dependent on various conditions of the plasma including, electron temperature, electron density, etc., where the rise time of the pulse is substantially equal to or less than the inverse of the electron plasma frequency. The duration of the pulse is less than the inverse of the ion plasma frequency.

Each of the rapidly-rising-electric-field pulses supplied through the electrodes 50₁ . . . 50₃ causes the electrons in the plasma proximate the respective electrode to accelerate or decelerate. This modifies the average electron temperature and modifies ionization, dissociation and other electron impact processes of the portions of the plasma 5 which translates to locally modifying the EED of the plasma. This makes it possible to control electron energy separately from the ions of the plasma. In addition, since the rise in the magnitude of the electric field pulse is faster than the electron response time, the electric field is established locally with respect to the portion of the plasma proximate to a particular electrode because the E-field is created before the ions have enough time to respond. Thus, the energy of the electrons in the plasma are affected by the electric field generated by each of the electrodes. Consequently, the uniformity of the plasma ions and neutrals corresponding to each of the electrodes can be modified. In this manner, the E-field distribution in the plasma can be used to selectively and locally modify the ion and neutral uniformity of the plasma.

FIG. 2 is a perspective view of a partitioned electrode assembly defined by electrodes 150₁ . . . 150₄ configured as a ring. In particular, first electrode 150₁ is generally circular having a first diameter and is disposed in the center of the ring. The second electrode 150₂ is configured as a ring radially displaced from first electrode 150₁ and has a second diameter which is greater than the first diameter associated with first electrode 150₁. The third electrode 150₃ is configured as a ring radially displaced from second electrode 150₂ and has a third diameter which is greater than the second diameter associated with second electrode 150₂. The fourth electrode 150₄ is configured as a ring radially displaced from third electrode 150₃ and has a fourth diameter which is greater than the third diameter associated with third electrode 150₃.

FIG. 2A is a perspective view of a plasma chamber 115 including a pedestal 125, walls 165 and top hat portion 160. Four (4) electrodes 150₁ . . . 150₄ are disposed within a top section 116 of the chamber to create rapidly-rising-electric-fields within the plasma. A plurality of dielectric rings 145₁ . . . 145₄ are disposed on top of respective electrode rings 150₁ . . . 150₄ to insulate each of the electrodes respectively. As can be seen, the electrodes 150₁ . . . 150₄ are centered above pedestal 125. The top section 116 of chamber 115 may be made from ceramic and covered by a top hat portion 160 (shown as translucent) made from, for example, aluminum. In addition, the walls 165 (also shown as translucent) of the chamber 115 may also be made from a conducting material such as, for example, aluminum. Each of the electrodes 150₁ . . . 150₄ are configured as rings comprising a first electrode, 150₁, second electrode 150₂, third electrode 150₃ and fourth electrode 150₄. Each of the electrode rings may be biased with respective voltages where a rapidly-rising voltage pulse V₁ is applied to first electrode 150₁, a rapidly-rising voltage pulse V₂ is applied to first electrode 150₂, a rapidly-rising voltage pulse V₃ is applied to first electrode 150₃, and a rapidly-rising voltage pulse V₄ is applied to fourth electrode 150₄. The rapidly-rising-electric-field pulses created from each of the electrodes 150₁ . . . 150₄ modifies the EED of the electrons in the plasma.

FIGS. 2B-2D illustrate exemplary E-field contours resulting from various voltages applied to respective electrodes 150₁ . . . 150₄. Each of the electrodes 150₁ . . . 150₄ is insulated from the top hat portion 160 by respective insulators 145₁ . . . 145₄. In particular, FIG. 2B illustrates E-field contours for the peak voltage values of V₁=−800V applied to electrode 150₁, V₂=−400V applied to electrode 150₂, V₃=−200V applied to electrode 150₃ and V₄=−100V applied to electrode 150₄. As can be seen, the E-field at electrode 150₁ having a rapidly-rising-pulse with a peak voltage of −800V and the E-field at electrode 150₂ having a rapidly-rising-pulse with a peak voltage of −400V generate electric fields locally into that portion of plasma 105 which is greater than the E-field generated proximate electrodes 150₃ and 150₄.

FIG. 2C illustrates E-field contours for the voltage values of V₁=−800V applied to electrode 150₁, V₂=−100V applied to electrode 150₂, V₃=−400V applied to electrode 150₃ and V₄=−200V applied to electrode 150₄. As can be seen, the E-field at electrode 150₁ having a rapidly-rising-pulse with a peak voltage of −800V and the E-field at electrode 150₃ having a rapidly-rising-pulse with a peak voltage of −400V generate electric fields locally into that portion of plasma 105 which is greater than the E-field generated proximate electrodes 150₁ and 150₄.

FIG. 2D illustrates E-field contours for the voltage values of V₁=−100V applied to electrode 150₁, V₂=−200V applied to electrode 150₂, V₃=−400V applied to electrode 150₃ and V₄=−800V applied to electrode 150₄. As can be seen, the E-field at electrode 150₄ having a rapidly-rising-pulse with a peak voltage of −800V and the E-field at electrode 150₃ having a rapidly-rising-pulse with a peak voltage of −400V generate electric fields locally into that portion of plasma 105 which is greater than the E-field generated proximate electrodes 150₁ and 150₂. Thus, the contours shown in FIGS. 2B-2D illustrate that the E-fields in plasma 105 can be locally modified using a plurality of electrodes which in turn provides spatial control of the properties of the generated plasma.

FIGS. 2E-2G illustrate exemplary E-field arrow vectors corresponding to the same voltage conditions of FIGS. 2B-2D. In particular, FIG. 2E shows the change of direction of the E-field vectors near the electrodes 150₁ . . . 150₄ having voltage values of V₁=−800V, V₂=−400V, V₃=−200V and V₄=−100V respectively. FIG. 2F shows the change of direction of the E-field vectors near the electrodes 150₁ . . . 150₄ having voltage values of V₁=−800V, V₂=−100V, V₃=−400V and V₄=−200V respectively. FIG. 2G shows the change of direction of the E-field vectors near the electrodes 150₁ . . . 150₄ having voltage values of V₁=−100V, V₂=−200V, V₃=−400V and V₄=−800V respectively. Based on the change of E-field vectors for each of the electrodes 150₁ . . . 150₄, this indicates that the EED of the plasma may be locally modified based on the rapidly-rising-electric-field pulses applied through each of the electrodes.

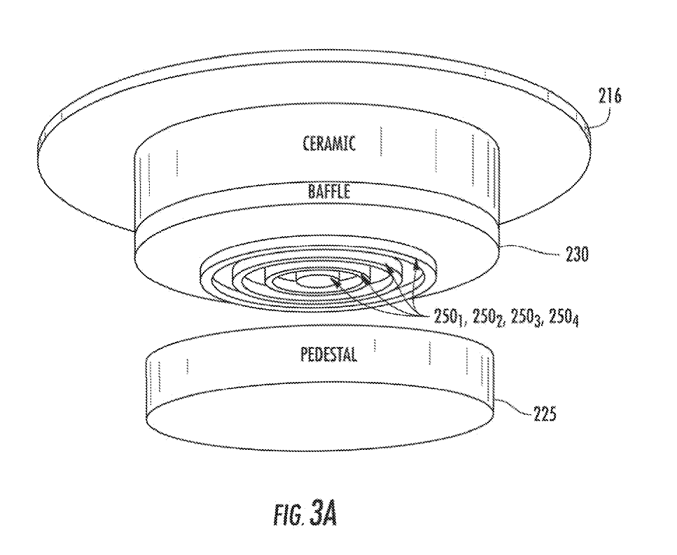

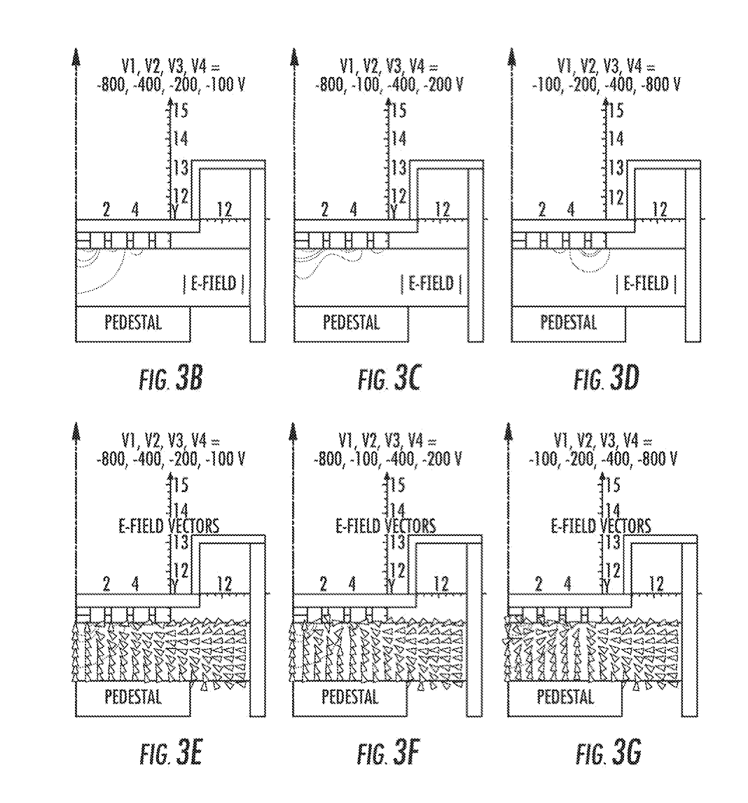

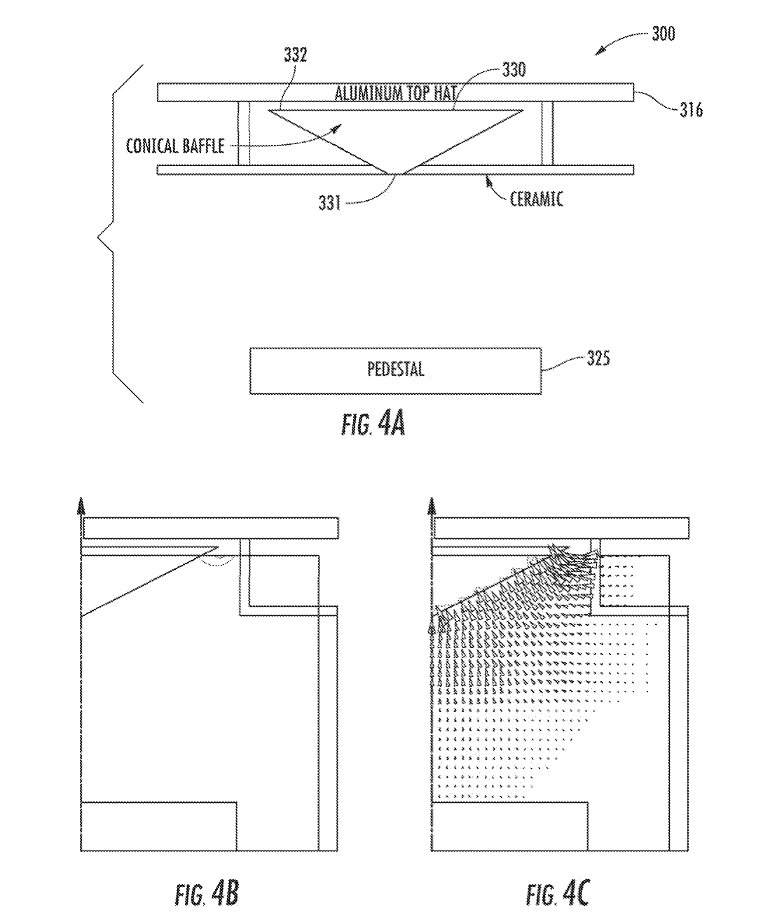

FIG. 3A is a perspective view of an alternative embodiment of a plasma chamber 215 utilizing a top section for an inverted RF source to generate plasma. In particular, plasma chamber includes a pedestal 225, a top section 216 and a plurality of electrodes 250₁ . . . 250₄ in the form of a ring to create rapidly-rising-electric-fields within the plasma. A baffle 230 is disposed between electrodes 250₁ . . . 250₄ and top section 216. A plurality of dielectric rings (not shown) are disposed between corresponding electrodes 250₁ . . . 250₄ and baffle 230 to insulate the electrodes from the baffle. As can be seen, the electrodes 250₁ . . . 250₄ are centered above pedestal 225. This inverted top section configuration allows the plurality of electrodes to be closer to the pedestal 225. Consequently, the magnitude of the E-field is larger and penetration of the E-field into the plasma is greater as compared to that shown with reference to FIGS. 2A-2G. This results in larger local modification of the EED in the plasma.

FIGS. 3B-3D illustrate exemplary E-field contours resulting from various voltages applied to respective electrodes 250₁ . . . 250₄. In particular, FIG. 3B illustrates E-field contours for the voltage values of V₁=−800V applied to electrode 250₁, V₂=−400V applied to electrode 250₂, V₃=−200V applied to electrode 250₃ and V₄=−100V applied to electrode 250₄. As can be seen, the E-field at electrode 250₁ having a rapidly-rising pulse with a peak voltage of −800V and the E-field at electrode 150₂ having a rapidly-rising pulse with a peak voltage of −400V generate electric fields locally into that portion of plasma 205 which is greater than the E-field generated proximate electrodes 250₃ and 250₄.

FIG. 3C illustrates E-field contours for the voltage values of V₁=−800V applied to electrode 250₁, V₂=−100V applied to electrode 250₂, V₃=−400V applied to electrode 250₃ and V₄=−200V applied to electrode 250₄. As can be seen, the E-field at electrode 250₁ having a rapidly-rising pulse with a peak voltage of −800V and the E-field at electrode 250₃ having a rapidly-rising pulse with a peak voltage of −400V generate electric fields locally into that portion of plasma which is greater than the E-field generated proximate electrodes 250₁ and 250₄. FIG. 3D illustrates E-field contours for the voltage values of V₁=−100V applied to electrode 250₁, V₂=−200V applied to electrode 250₂, V₃=−400V applied to electrode 250₃ and V₄=−800V applied to electrode 250₄. As can be seen, the E-field at electrode 250₄ having a rapidly-rising pulse with a peak voltage of −800V and the E-field at electrode 250₃ having a rapidly-rising pulse with a peak voltage of −400V generate electric fields locally into that portion of plasma which is greater than the E-field generated proximate electrodes 250₁ and 250₂. Thus, the contours shown in FIGS. 3B-3D illustrate that the E-fields in the plasma can be locally modified using a plurality of electrodes which in turn provides spatial control of the properties of the generated plasma.

FIGS. 3E-3G illustrate exemplary E-field vectors corresponding to the same voltage conditions of FIGS. 3B-3D. In particular, FIG. 3E shows the change of direction of the E-field vectors near the electrodes 250₁ . . . 250₄ having voltage values of V₁=−800V, V₂=−400V, V₃=−200V and V₄=−100V respectively. FIG. 3F shows the change of direction of the E-field vectors near the electrodes 250₁ . . . 250₄ having voltage values of V₁=−800V, V₂=−100V, V₃=−400V and V₄=−200V respectively. FIG. 3G shows the change of direction of the E-field vectors near the electrodes 250₁ . . . 250₄ having voltage values of V₁=−100V, V₂=−200V, V₃=−400V and V₄=−800V respectively. Based on the change of E-field vectors for each of the electrodes 250₁ . . . 250₄, this indicates that the EED of the plasma may be locally modified based on the rapidly-rising-electric-field pulses applied through each of the electrodes.

FIG. 4A is a general (excluding chamber walls) side view of an alternative embodiment of plasma chamber 300 utilizing a conical baffle which is biased to provide various E-fields in a generated plasma. In particular, plasma chamber 300 includes a top-hat portion 316, pedestal 325 and baffle 330 centered above pedestal 325 upon which a target substrate is disposed. Baffle 330 is shown as having a conical shape, but other configurations where one or more portions of the surface of the baffle facing pedestal 325 (and consequently a target substrate) is closer to the generated plasma may be employed. Rapidly-rising-electric-field pulses are supplied through the entire baffle 330 to the plasma by a pulse generator (not shown). Since the center portion 331 of baffle 330 is closer to the plasma than the outer portion 332, the effect of the generated electric field pulse from portion 331 on the plasma is greater than the effect of the generated electric field pulse on the plasma from portion 332. In this manner, by shaping the baffle and biasing it for use as the electrode assembly, an electric field generated in the plasma may spatially be modified, thereby controlling the EED of particular electrons in the plasma.

FIG. 4B illustrates E-field contours for rapidly-rising pulse with a peak voltage of −800 V applied to the conical shaped baffle 330. As can be seen, the E-field effects on the generated plasma are higher at the center portion 331 of baffle 330 than at the edges 332. FIG. 4C illustrates E-field arrow vectors for the voltage values applied to the baffle 330. This spatial non-uniformity in the E-field generated by the pulses applied to the conically shaped baffle 330 can be used to locally modify the plasma properties. In this manner, the density, temperature and composition of ions and neutrals in the plasma may be locally modified.

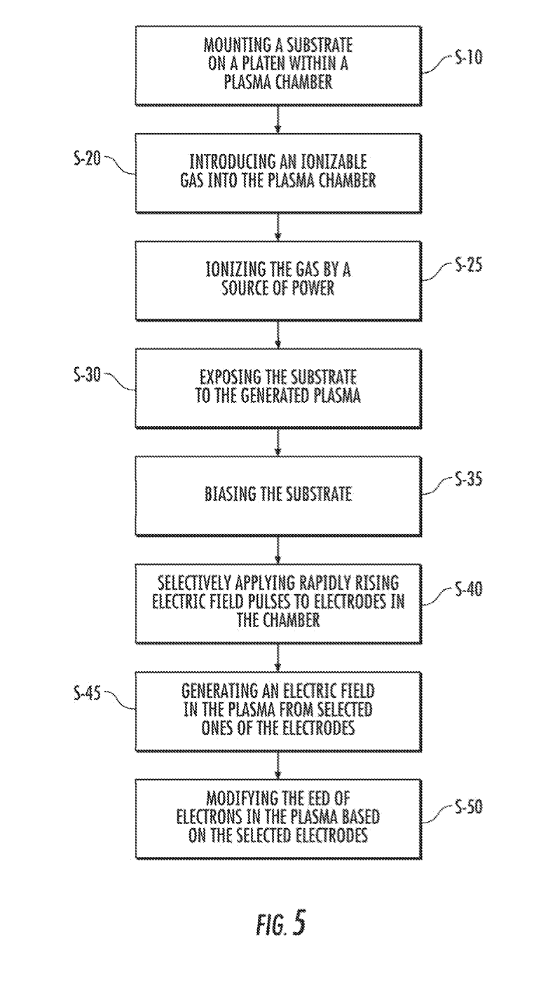

FIG. 5 is a flow diagram illustrating the steps associated with modifying an electron energy distribution of a plasma in a plasma chamber to control the uniformity of plasma directed at a target substrate. A target substrate is mounted on a platen or pedestal within the plasma chamber at step S-10. An ionizable gas is introduced into the chamber at step S-20 and the gas is ionized by a source of power, such as RF, at step S-25 to generate a plasma having ions, electrons and neutrals. The substrate is exposed to the generated plasma at step S-30. Rapidly-rising-electric-field pulses are selectively applied through a plurality of electrodes disposed within the chamber at step S-40. At step S-45, an electric field is generated in the plasma from the selected ones of the plurality of electrodes. At step S-50, the EED of the electrons in the plasma is modified based on the particular groupings of ions, electrons and neutrals in the plasma proximate the selected electrodes that generate the corresponding electric fields. In this manner, the EED in the plasma may be selectively and locally modified thereby controlling the ion/neutral density uniformity. The target substrate is then biased at step S-60 which attracts the accelerated positive ions toward the platen for implantation into the target substrate.

While the present invention has been disclosed with reference to certain embodiments, numerous modifications, alterations and changes to the described embodiments are possible without departing from the sphere and scope of the present invention, as defined in the appended claims. Accordingly, it is intended that the present invention not be limited to the described embodiments, but that it has the full scope defined by the language of the following claims, and equivalents thereof.

What is claimed is:

1. A plasma processing tool comprising:
a plasma chamber configured to generate a plasma from a gas introduced into the chamber, said plasma having an electron plasma frequency; and
a plurality of electrodes disposed within said chamber, each of the plurality of electrodes configured to generate a rapidly-rising-electric-field pulse in a corresponding portion of the plasma contained in the chamber, each of said rapidly-rising-electric-field pulses having a rise time substantially equal to or less than the inverse of the electron plasma frequency and a duration of substantially equal to or less than the inverse of the ion plasma frequency.

2. The plasma processing tool of claim 1 further comprising a pedestal disposed within said plasma chamber and configured to support a target substrate.

3. The plasma processing tool of claim 2 wherein each of said plurality of electrodes are disposed a distance above said pedestal.

4. The plasma processing tool of claim 2 further comprising a baffle disposed at a first end of said plasma chamber a distance away from said pedestal.

5. The plasma processing tool of claim 4 further comprising an insulator disposed between each of said plurality of electrodes and said baffle.

6. The plasma processing tool of claim 4 wherein said plurality of electrodes are configured as a ring.

7. The plasma processing tool of claim 1 wherein said plurality of electrodes further comprises a first electrode ring having a first diameter, a second electrode ring radially displaced from said first electrode ring and having a second diameter greater than said first diameter, and a third electrode ring radially displaced from said second electrode ring and having a third diameter greater than said second diameter.

8. The plasma processing tool of claim 7 wherein each of said first, second and third electrode rings convey a rapidly-rising-electric-field pulse through the plasma each at respective magnitude and phase.

9. The plasma processing tool of claim 7 further comprising a fourth electrode ring radially disposed from said third electrode ring and having a fourth diameter greater than said third diameter.

10. The plasma processing tool of claim 1 further comprising a plurality of rapidly-rising-electric-field pulse generators each connected to a corresponding one of said plurality of electrodes for supplying respective rapidly-rising-electric-field pulses through said electrodes to the plasma.

11. The plasma processing tool of claim 1 wherein each of the rapidly-rising-electric-field pulses generated by the plurality of electrodes are synchronous within a time duration.

12. The plasma processing tool of claim 1 wherein each of the rapidly-rising-electric-field pulses generated by the plurality of electrodes are asynchronous within a time duration.

13. A plasma processing tool comprising:
a plasma chamber configured to generate a plasma from a gas introduced into the chamber, said plasma having charged and non-charged species and an associated electron plasma frequency;
a pedestal disposed within said chamber; and
a conductive baffle supported within the chamber and insulated from said chamber, the baffle having a surface disposed toward said plasma, said surface having an irregular shape wherein a first portion of said surface is closer to said plasma than a second portion of said surface, said baffle configured to create a rapidly-rising-electric-field pulse in the plasma contained in the chamber wherein said first portion of said baffle generates a higher electric field within said plasma than said second portion such that said electric fields modify at least one of a density, composition and temperature of the charged and non-charged species in the plasma.

14. A plasma processing tool of claim 13 wherein said rapidly-rising-electric-field pulse has a duration of substantially equal to or less than the inverse of the ion plasma frequency.

15. A method for modifying an electron energy distribution of a plasma comprising:
providing a feed gas to a chamber;
exciting the feed gas to generate a plasma having ions, electrons and neutrals;
selectively applying a rapidly-rising-electric-field pulse through selected ones of a plurality of electrodes disposed within said chamber;
generating an electric field in the plasma from the selected ones of said plurality of electrodes; and
affecting the uniformity of the density and composition of particular groupings of ions, electrons and neutrals in the plasma based on the generation of the corresponding electric fields by the selected electrodes.

16. The method of claim 15 further comprising modifying the electron temperature and energy of the electrons in the plasma based on the electric fields generated in the plasma.

17. The method of claim 15 wherein a plurality of rapidly-rising-electric-field pulses are selectively generated through each of the selected ones of a plurality of electrodes.

18. The method of claim 17 further comprising generating each of the plurality of rapidly-rising-electric-field pulses synchronously.

19. The method of claim 17 further comprising generating each of the plurality of rapidly-rising-electric-field pulses asynchronously.

20. A method for modifying an electron energy distribution of a plasma comprising:
generating a plasma having an associated electron plasma frequency in a plasma chamber; and
applying a rapidly-rising-electric-field pulse through a plurality of electrodes disposed in the plasma chamber, each of said pulses having a duration of less than the inverse of the ion plasma frequency wherein the rapidly-rising-electric-field pulse affects electrons of the plasma.

21. The method of claim 20 further comprising modifying a magnitude of the applied rapidly-rising-electric-field pulse to a first of the plurality of electrodes.

22. The method of claim 21 further comprising introducing a source gas into said chamber.

23. The method of claim 21 further comprising ionizing said feed gas in said chamber to create said plasma.

24. The method of claim 20 wherein each of the plurality of rapidly-rising-electric-field pulses are applied synchronously.

25. The method of claim 20 wherein each of the plurality of rapidly-rising-electric-field pulses are applied asynchronously.

26. The method of claim 20 wherein the rapidly-rising-electric-field pulse affects electrons of the plasma, but does not substantially affect ions of the plasma.

27. A plasma processing tool comprising:
a plasma chamber configured to generate a plasma from a gas introduced into the chamber, said plasma having an electron plasma frequency; and
an electrode disposed within said chamber configured to generate a rapidly-rising-electric-field pulse in a corresponding portion of the plasma contained in the chamber, said rapidly-rising-electric-field pulse having a rise time substantially equal to or less than the inverse of the electron plasma frequency and a duration of substantially equal to or less than the inverse of the ion plasma frequency.
